(19) United States
(12) Patent Application Publication
(10) Pub. No.: US 2023/0411177 A1
(43) Pub. Date: Dec. 21, 2023

(54) APPARATUS FOR PROCESSING A WAFER-SHAPED ARTICLE

(71) Applicant: LAM RESEARCH AG, Villach (AT)

(72) Inventors: Karl-Heinz HOHENWARTER, Dellach/Gail (AT); Bhaskar BANDARAPU, Villach (AT); Christian PUTZI, Rosenbach (AT)

(21) Appl. No.: 18/032,397

(22) PCT Filed: Oct. 14, 2021
(86) PCT No.: PCT/EP2021/078522

§ 371 Date: Apr. 18, 2023

(30) Foreign Application Priority Data
Oct. 22, 2020 (GB) 2016750.8

(51) Int. Cl. H01L 21/67

(52) U.S. Cl. CPC H01L 21/67023

(57) ABSTRACT

An apparatus for processing a wafer-shaped article, the apparatus comprising: a support for supporting the wafer-shaped article; and a liquid dispenser for dispensing a processing liquid onto a surface of the wafer-shaped article supported by the support; wherein the liquid dispenser comprises a nozzle assembly, the nozzle assembly comprising: an inlet portion; a dispensing nozzle; and a static throttle between the inlet portion and the dispensing nozzle, the static throttle comprising a plurality of flow passages through which the processing liquid can flow from the inlet portion to the dispensing nozzle.

### FIELD OF THE INVENTION

The present invention relates to an apparatus for processing a wafer-shaped article, and also to a nozzle assembly for use in such an apparatus.

### BACKGROUND OF THE INVENTION

Semiconductor wafers may be subjected to various surface treatment processes, such as etching, cleaning, polishing and material deposition.

At least some of these surface treatment processes involve applying a liquid to a surface of the wafer. For example, the surface of the wafer may be etched by applying a processing liquid such as hydrofluoric acid to selected locations on the surface of the wafer. Alternatively, the surface of the wafer may be cleaned by applying a cleaning liquid or rinse liquid such as isopropyl alcohol or de-ionised water to the surface of the wafer.

The wafer may be spun when the liquid is applied to the surface of the wafer, for example using a rotatable chuck that holds the wafer, to assist the distribution of the liquid over the surface of the wafer. Where the liquid is a cleaning liquid or a rinse liquid, such a process may be referred to as a spin-clean process.

In addition, the surface of the wafer may subsequently be dried by heating the wafer to cause evaporation of the liquid on the surface of the wafer.

An example of an apparatus that may be used for liquid treatment of a semiconductor wafer is described in US2017/0345681A1, the contents of which are incorporated herein by reference.

A further example of an apparatus that may be used for liquid treatment of a semiconductor wafer is described in U.S. Pat. No. 9,799,539B2, the contents of which are also incorporated herein by reference.

As discussed in U.S. Pat. No. 9,799,539B2, stray droplets from a liquid dispenser that is used to dispense liquid onto the surface of the wafer may result in damage to the wafer, meaning that the wafer may be defective and may need to be discarded. For example, where the liquid is a processing liquid used to etch the surface of the wafer, the stray droplets may cause the wafer to be incorrectly etched.

U.S. Pat. No. 9,799,539B2 discloses an apparatus for liquid treatment of a wafer-shaped article that aims to prevent such stray droplets from being produced.

As shown in FIG. 1 (which corresponds to FIG. 1 of U.S. Pat. No. 9,799,539B2), U.S. Pat. No. 9,799,539B2 discloses an apparatus that comprises a spin chuck 1 for holding a wafer W. For example, spin chuck 1 may comprise a series of gripping pins that support the wafer W. Spin chuck 1 is positioned within a chamber 2, and is typically present in a process module for single wafer wet processing of semiconductor wafers. A liquid dispenser assembly is positioned above the chuck 1 and comprises a liquid dispenser arm 4 that is connected to a supply 5 of a process liquid, via a control valve 6. The liquid dispenser arm 4 comprises a nozzle assembly 3 at its distal end. The liquid dispenser arm 4 is preferably pivotable or movable linearly to a standby position in which it does not overlie the wafer W, to facilitate loading and unloading of the wafer W on the spin chuck 1.

Spin chuck 1 is rotated via a lower shaft that in turn is driven in rotation by a motor 7. A controller 8 controls the overall operation of the spin chuck 1, including coordinating the action of the motor 7 to rotate the spin chuck 1 and the action of the valve 6 to open and close the flow of process liquid from the supply 5.

As shown in FIG. 2 (which corresponds to FIG. 2 of U.S. Pat. No. 9,799,539B2), the nozzle assembly 3 in U.S. Pat. No. 9,799,539B2 comprises a check valve 9 positioned within the nozzle assembly 3. The check valve 9 includes a valve element 10 that is urged towards a closed position against a valve seat 11 by a helical spring 12.

In use of the apparatus disclosed in U.S. Pat. No. 9,799,539B2, a wafer W is positioned on the spin chuck 1 and controller 8 signals motor 7 to rotate the wafer at a selected rpm. Controller 8 next signals control valve 6 to open the supply 5 of process liquid to the dispenser arm 4.

As the process liquid enters into nozzle assembly 3 from the inlet/upstream side (the top of the nozzle assembly in FIG. 2), the supply pressure of the process liquid is sufficient to displace the valve element 10 downwardly, off of the valve seat 11, so that process liquid can continue to flow through the nozzle assembly 3 and out of an outlet/downstream side of the nozzle assembly 3 (the bottom of the nozzle assembly in FIG. 2). The process liquid is discharged from the nozzle assembly 3 from the outlet/downstream side onto the wafer W.

At the conclusion of the desired treatment of the wafer W with the process liquid, the controller 8 signals the control valve 6 to close. As the pressure of the process liquid in the nozzle assembly 3 drops, the valve element 10 is urged by spring 12 to return to its closed position against the valve seat 11.

Therefore, the check valve in the nozzle assembly 3 closes substantially immediately after the desired flow stops, and does not allow for the process liquid to drip after the desired flow, for example during movement of the dispenser arm following the desired flow.

### SUMMARY OF THE INVENTION

While the arrangement disclosed in U.S. Pat. No. 9,799,539B2 has proven to be effective at preventing unwanted dripping of the process liquid, and is well suited for many applications, the present inventors have realised that in some circumstances the arrangement disclosed in U.S. Pat. No. 9,799,539B2 may have some undesirable effects.

For example, in some circumstances the check valve used in U.S. Pat. No. 9,799,539B2 may generate or trap particles, because of the moving parts of the check valve, which is undesirable. For example, generated particles may cause some contamination of the processing liquid and/or wafer.

The present invention aims to address this problem.

At its most general, the present invention relates to a liquid dispenser for an apparatus for processing wafer-shaped articles, wherein a nozzle of the liquid dispenser includes a static throttle that comprises a plurality of flow passages.

The present inventors have discovered that including such a static throttle in the nozzle can help to prevent drips being generated when the supply of processing liquid is stopped. Furthermore, since the static nozzle does not include any moving parts, the static nozzle does not generate or trap particles in the same way as the check valve in U.S. Pat. No. 9,799,539B2.

According to a first aspect of the present invention there is provided an apparatus for processing a wafer-shaped article, the apparatus comprising:
a support for supporting the wafer-shaped article; and
a liquid dispenser for dispensing a processing liquid onto a surface of the wafer-shaped article supported by the support;
wherein the liquid dispenser comprises a nozzle assembly, the nozzle assembly comprising:
   an inlet portion;
   a dispensing nozzle; and
   a static throttle between the inlet portion and the dispensing nozzle, the static throttle comprising a plurality of flow passages through which the processing liquid can flow from the inlet portion to the dispensing nozzle.

The present inventors have found that providing such a nozzle assembly in the liquid dispenser can help to prevent drips being generated when the supply of processing liquid is stopped. Furthermore, since the static nozzle does not include any moving parts, the static nozzle does not generate or trap particles in the same way as the check valve in U.S. Pat. No. 9,799,539B2.

The apparatus according to the first aspect of the present invention may have any one, or, where compatible, any combination of the following optional features.

The wafer-shaped article may be a semiconductor wafer.

Processing of the wafer-shaped article may comprise liquid treatment of a surface of the wafer-shaped article. For example, the treatment may comprise etching or rinsing of the surface.

The support may be a chuck.

The support may be rotatable so as to rotate the wafer-shaped article. For example, the support may be a rotatable chuck, such as a spin chuck. The apparatus may comprise a motor for rotating the support.

The liquid dispenser is a mechanism, or system, or arrangement, for dispensing liquid.

The apparatus may comprise a supply of processing liquid for supplying processing liquid to the liquid dispenser.

The liquid dispenser may comprise a dispensing arm, and the nozzle assembly may be located at, or adjacent to, a distal end of the dispensing arm. A flow path may be provided inside the dispensing arm for supplying processing liquid to the nozzle assembly.

The dispensing arm may be rotatably mounted or pivoted at a proximal end of the dispensing arm, so that the dispensing arm can be moved over the surface of the wafer-shaped article.

More generally, the nozzle assembly may be movable over the surface of the wafer-shaped article, in order to dispense processing liquid on different parts of the wafer-shaped article. For example, the apparatus may comprise an X-Y stage, or an X-Y-Z stage, for moving the nozzle assembly relative to the wafer-shaped article.

The term nozzle assembly may be replaced with the term nozzle, or nozzle arrangement, or nozzle member, or nozzle element, or nozzle part.

The inlet portion of the nozzle assembly is a part or portion of the nozzle assembly where processing liquid is input into the nozzle assembly.

For example, the inlet portion of the nozzle assembly may comprise a flow passage or chamber in the nozzle assembly that is connectable to a flow of processing liquid.

The dispensing nozzle is a part or portion of the nozzle assembly from which the processing liquid is dispensed (output) from the nozzle assembly. In practice therefore the dispensing nozzle will have a nozzle tip from which the processing liquid is dispensed from the nozzle assembly.

In practice, the processing liquid will be dispensed from the dispensing nozzle directly onto the surface of the wafer-shaped article.

In general, the term static throttle means a portion, or member, or element, that throttles the flow of processing liquid through the nozzle assembly and that has no moving parts. Throttling the flow of the processing liquid may mean narrowing the flow of the processing liquid, or resisting the flow of the processing liquid, or restricting the flow of the processing liquid.

The static throttle is positioned between the inlet portion and the dispensing nozzle. For example, the static throttle may directly connect the inlet portion to the dispensing nozzle, and/or partition the inlet portion from the dispensing nozzle.

The plurality of flow passages are separate and/or individual and/or distinct flow passages, with respective inlets and outlets.

The plurality of flow passages have inlets on an inlet portion side of the static throttle and outlets on a dispensing nozzle side of the static throttle.

The term flow passages may instead be replaced with the term flow paths, or channels, or bores, or bore holes.

The plurality of flow passages may comprise a plurality of bore holes.

The plurality of bore holes may be machined in a block of material. Alternatively the nozzle can be made by 3D-printing (additive manufacturing).

There may be greater than, or equal to, five flow passages, or greater than or equal to nine flow passages, or greater than or equal to fifteen flow passages.

At least part of an internal surface of the dispensing nozzle may be hydrophilic. For example, at least the internal surface of the dispensing nozzle at or adjacent to the outlets of the plurality of flow passages may be hydrophilic.

Substantially, or entirely, the whole internal surface of the dispensing nozzle may be hydrophilic.

Substantially, or entirely, the whole internal surface of the nozzle assembly may be hydrophilic.

Hydrophilic may mean that the surface comprises a material that has a static water contact angle of less than or equal to 90°, or less than or equal to 80°, or less than or equal to 45°.

The hydrophilic surface may comprise PCTFE or PFA.

Substantially, or entirely, the whole of the dispensing nozzle may be formed from a hydrophilic material, such as PCTFE or PFA.

Substantially, or entirely, the whole of the nozzle assembly may be formed from a hydrophilic material, such as PCTFE or PFA.

Providing such a hydrophilic internal surface helps to prevent drips from being generated when the supply of processing liquid is stopped.

A length of the dispensing nozzle may be at least four times an internal diameter of the dispensing nozzle, or at least five times an internal diameter of the dispensing nozzle, or at least six times an internal diameter of the dispensing nozzle, or at least seven times an internal diameter of the dispensing nozzle.

The present inventors have found that with such a length of the dispensing nozzle the individual flows through the plurality of flow passages have sufficient space to merge to form a well-developed and substantially uniform velocity profile at the end of the dispensing nozzle, even at different flow rates through the nozzle assembly.

An internal diameter or width of the inlet portion may be greater than an internal diameter or width of the dispensing nozzle.

More generally, a diameter or width of the fluid flow through the nozzle assembly may be narrowed on passing through the static throttle. The static throttle therefore causes necking or narrowing of the fluid flow through the nozzle assembly.

For at least some of the plurality of flow passages, an outlet of the flow passage may be closer to a central axis of the nozzle assembly than an inlet of the flow passage. The diameter or width of the fluid flow is therefore narrowed on passing through the static throttle.

Inlets of the flow passages on the inlet portion side of the static throttle may span or cover or extend across a larger surface area than outlets of the flow passages on the dispensing nozzle side of the static throttle.

In other words, an envelope of the inlets of the flow passages on the inlet portion side may be larger than an envelope of the outlets of the flow passages on the dispensing nozzle side.

The flow passages may be substantially, or entirely, linear (straight).

Some of the flow passages may be at an angle relative to a central axis of the nozzle assembly, so that an outlet of the flow passage is closer to the central axis than an inlet of the flow passage.

At least some of the flow passages may be parallel to the central axis of the nozzle assembly. For example, one or more central flow passages may extend parallel to the central axis of the nozzle assembly, and one or more peripheral flow passages may be angled relative to the central axis of the nozzle assembly so that their outlets are closer to the central axis than their inlets.

The nozzle assembly may be machined from a single piece of material.

At least part of an internal surface of the dispensing nozzle has a surface roughness Ra of less than or equal to or less than or equal to 0.4 μm, or less than or equal to 0.3 μm, or less than or equal to 0.2 μm.

Substantially, or entirely, the whole internal surface of the dispensing nozzle may have such a surface roughness.

Substantially, or entirely, the whole internal surface of the nozzle assembly may have such a surface roughness.

The plurality of flow passages each have a diameter d in the range of 0.8 mm≤d≤1.6 mm.

The static throttle may comprise a concave or conical or tapered or funnel-shaped portion on the inlet portion side of the static throttle, with the opening of the portion facing the inlet portion. The inlets of the flow passages may be located on a bottom surface of this portion (a surface facing the dispensing nozzle).

The apparatus may further comprise a control valve for turning on and off a supply of processing liquid to the liquid dispenser, the control valve being positioned upstream of the nozzle assembly.

According to a second aspect of the present invention there is provided a nozzle assembly for use in an apparatus for processing a wafer-shaped article, the nozzle assembly comprising:
an inlet portion;
a dispensing nozzle; and
a static throttle between the inlet portion and the dispensing nozzle, the static throttle comprising a plurality of flow passages through which the processing liquid can flow from the inlet portion to the dispensing nozzle.

The nozzle assembly according to the second aspect of the present invention may have any one, or where compatible, any combination of the features of the nozzle assembly in the first aspect of the invention described above. These features are not described again here for conciseness.

### BRIEF DESCRIPTION OF THE DRAWINGS

Embodiments of the present invention will now be discussed, by way of example only, with reference to the accompanying Figures, in which:

FIG. 1 is a schematic illustration of an apparatus according to an embodiment of the present invention;

FIG. 2 is a cross-sectional view of a prior art nozzle assembly;

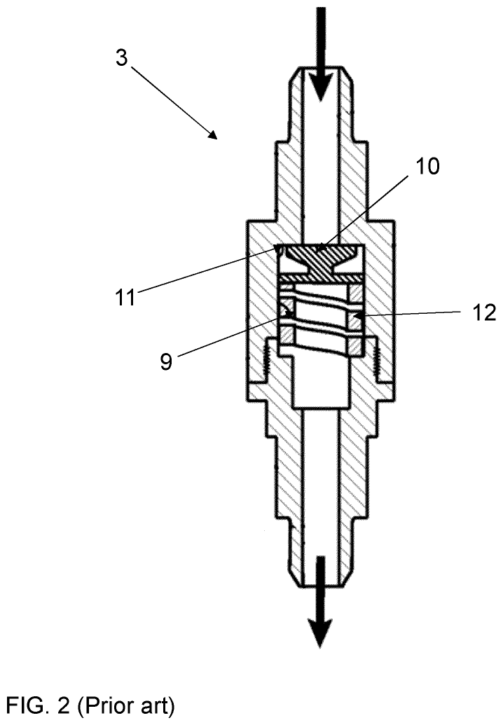

FIG. 3 is a schematic illustration of a nozzle assembly according to an embodiment of the present invention;

FIG. 4 is a plan view of the nozzle assembly illustrated in FIG. 3;

FIG. 5 is a schematic view of a nozzle assembly according to another embodiment of the present invention;

FIG. 6 is a plan view of the nozzle assembly illustrated in FIG. 5; and

FIG. 7 is an illustration of a computation fluid flow model for the nozzle assembly illustrated in FIGS. 5 and 6.

### DETAILED DESCRIPTION OF THE PREFERRED EMBODIMENTS AND FURTHER OPTIONAL FEATURES OF THE INVENTION

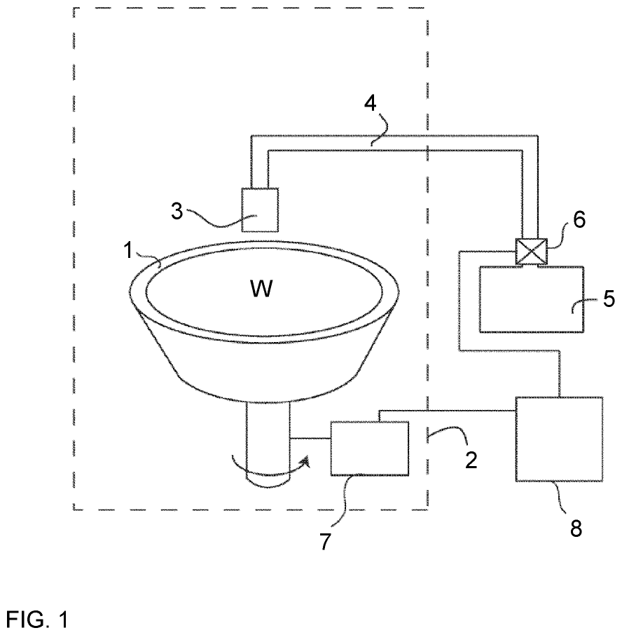

According to an embodiment of the present invention, an apparatus for liquid treatment of a semiconductor wafer may have the configuration illustrated in FIG. 1 and described above. This description is not repeated here for conciseness.

Of course, an apparatus according to the present invention may be different to the apparatus illustrated in FIG. 1. For example, the chuck may be a non-rotatable chuck, and/or may have a different shape and/or configuration to the chuck illustrated in FIG. 1.

The apparatus according to this embodiment differs from the apparatus disclosed in U.S. Pat. No. 9,799,539B2 at least in the configuration of the nozzle assembly 3.

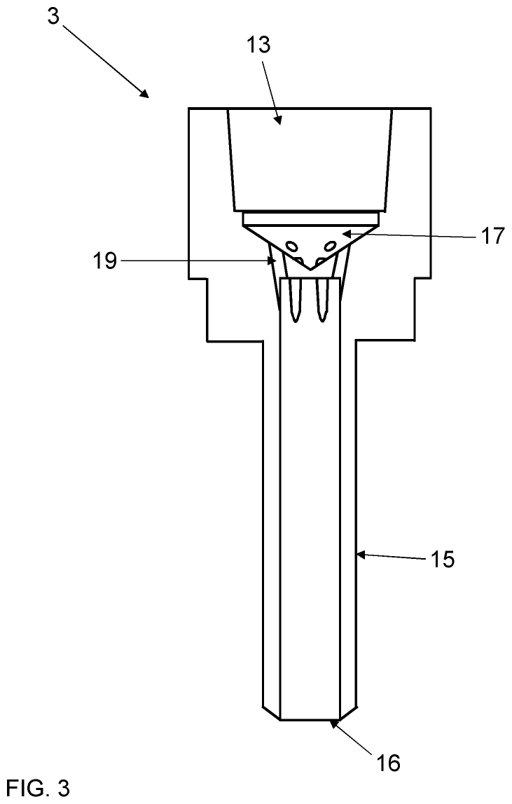

A nozzle assembly 3 according to an embodiment of the present invention is illustrated in FIG. 3.

As shown in FIG. 3, the nozzle assembly 3 comprises an inlet portion 13 and a dispensing nozzle 15 (or outlet portion 15). The inlet portion 13 is connected to a liquid flow path in the liquid dispenser arm 4, either directly or via one or more additional components, for example via an intermediate liquid flow path. Therefore, liquid can flow through the liquid flow path in the liquid dispenser arm 4 into the nozzle assembly 3 via the inlet portion 13.

Of course, the inlet portion 13 may have a different shape and/or configuration to that illustrated in FIG. 3. For example the length of the inlet portion 13 may be longer or shorter than that illustrated in FIG. 3, and/or the internal and/or external width of the inlet portion 13 may be more or less than that illustrated in FIG. 3, and/or the internal and/or external shape of the inlet portion 13 may be different to that illustrated in FIG. 3.

The dispensing nozzle 15 of the nozzle assembly 3 is for dispensing liquid from the nozzle assembly 3 onto the surface of the wafer W. In particular, liquid is directly dispensed from a tip 16 of the dispensing nozzle 15.

Of course, the dispensing nozzle 15 may have a different shape and/or configuration to that illustrated in FIG. 3. For example the length of the dispensing nozzle 15 may be longer or shorter than that illustrated in FIG. 3, and/or the internal and/or external width of the dispensing nozzle 15 may be more or less than that illustrated in FIG. 3, and/or the internal and/or external shape of the dispensing nozzle 15 may be different to that illustrated in FIG. 3.

A diameter (or width) of a fluid passageway (or fluid flowpath) in the inlet portion 13 of the nozzle assembly 3 is larger than a diameter (or width) of a fluid passageway (or fluid flowpath) in the dispensing nozzle 15 of the nozzle assembly 3.

A static throttle 17 is positioned between the inlet portion 13 and the dispensing nozzle 15 of the nozzle assembly 3. In particular, the static throttle 17 connects the inlet portion 13 to the dispensing nozzle 15.

The static throttle 17 restricts flow of liquid from the inlet portion 13 to the dispensing nozzle 15.

In general, the term static throttle means a portion, or member, or element, that throttles the flow of liquid through the nozzle assembly 3 and that has no moving parts.

The static throttle 17 comprises a plurality of bore holes 19 (or channels 19, or flow paths 19) that extend from the inlet portion 13 side of the static throttle 17 to the dispensing nozzle 15 side of the static throttle 17, and through which liquid can flow from the inlet portion 13 to the dispensing nozzle 15.

The static throttle 17 partitions the inlet portion 13 of the nozzle assembly 3 from the dispensing nozzle 15 of the nozzle assembly 3, such that liquid can only flow from the inlet portion 13 to the dispensing nozzle 15 through the plurality of bore holes 19 formed in the static throttle 17.

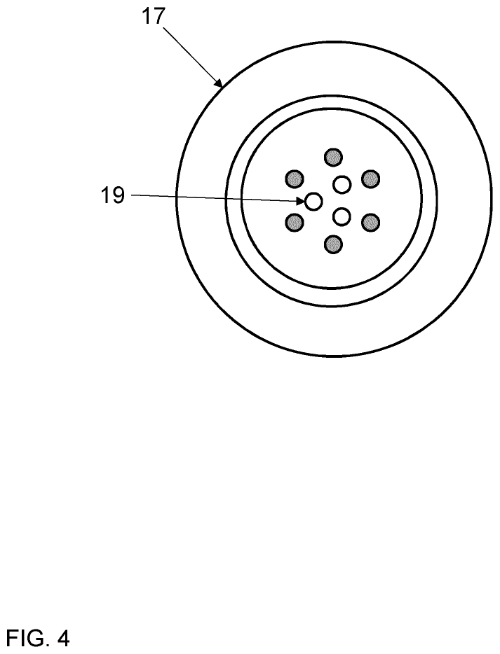

A plan view of the static throttle 17 is shown in FIG. 4. As shown in FIG. 4, in this embodiment the static throttle 17 comprises a pattern of nine bore holes 19. However, the specific number of bore holes 19 is not essential to the present invention, and instead it is only necessary for the static throttle 17 to comprise a plurality of bore holes 19.

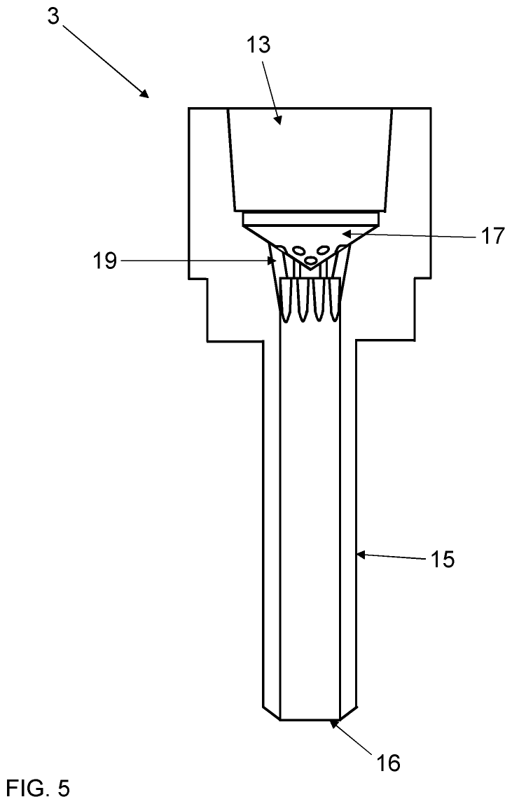

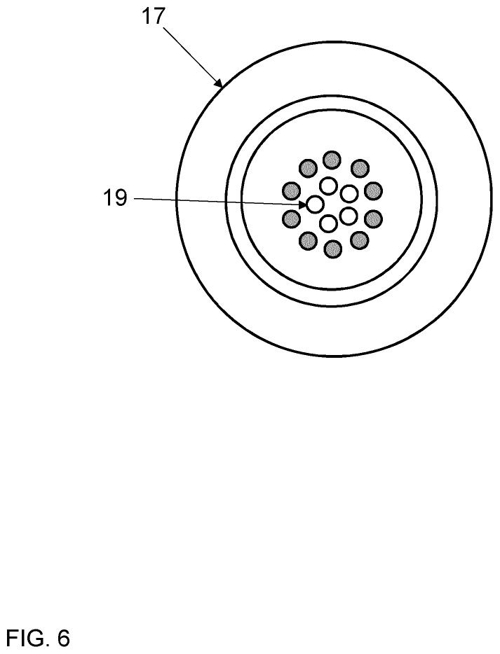

For example, FIGS. 5 and 6 illustrate an alternative embodiment of the present invention in which the static throttle 17 has fifteen bore holes 19 instead of nine bore holes 19.

Only some of the bore holes 19 are illustrated in FIGS. 3 and 5 for clarity.

In addition, it is not necessary for the bore holes 19 to be arranged in any particular pattern in the static throttle 17.

A diameter or width of the fluid flow through the nozzle assembly 3 is narrowed on passing through the static throttle 17. The static throttle 17 therefore causes necking of the fluid flow through the nozzle assembly 3.

In particular, inlets of the bore holes 19 on the inlet portion 13 side of the static throttle 17 span or cover or extend across a larger surface area than outlets of the bore holes 19 on the dispensing nozzle 15 side of the static throttle 17.

In other words, an envelope of the inlets of the bore holes 19 on the inlet portion 13 side is larger than an envelope of the outlets of the bore holes 19 on the dispensing nozzle 15 side of the static throttle 17.

For example, for at least some of the bore holes 19, outlets of the bore holes 19 are closer to a central axis of the nozzle assembly 3 than inlets of the bore holes 19.

In the embodiments illustrated in FIGS. 3 and 5, the bore holes 19 are substantially (or entirely) linear (straight) bore holes 19, and some of the bore holes 19 are at an angle relative to a central axis of the nozzle assembly, so that outlets of the bore holes 19 are closer to the central axis of the nozzle assembly 3 than inlets of the bore holes 19.

Substantially (or entirely) linear bore holes 19 are preferable, for example for ease of machining. However, in other embodiments the bore holes 19 may instead be non-linear, for example curved.

At least some of the bore holes 19 may be parallel to the central axis of the nozzle assembly 3. For example, in the embodiment illustrated in FIGS. 3 and 4, three central bore holes 19 extend parallel to the central axis of the nozzle assembly 3, and six peripheral bore holes 19 are angled relative to the central axis of the nozzle assembly 3 so that their outlets are closer to the central axis than their inlets.

Similarly, in the embodiments illustrated in FIGS. 5 and 6, five central bore holes 19 extend parallel to the central axis of the nozzle assembly 3, and ten peripheral bore holes 19 are angled relative to the central axis of the nozzle assembly 3 so that their outlets are closer to the central axis than their inlets.

The static throttle 17 may comprise a concave or conical or tapered or funnel-shaped portion on the inlet portion 13 side of the static throttle 17, and the inlets of the bore holes 19 may be located on a bottom surface of this portion.

The nozzle assembly 3 may be machined from a single block of material.

Preferably at least part of an internal surface of the dispensing nozzle 15 of the nozzle assembly 3 is hydrophilic. For example, substantially (or entirely) the whole internal surface of the dispensing nozzle 15 may be hydrophilic. Hydrophilic may mean that the surface comprises a material that has a static water contact angle of less than 90°. In some embodiments the material may have a static water contact angle of less than 80°, or less than 45°.

This may be achieved by forming the dispensing nozzle 15 from a hydrophilic material, or by applying a hydrophilic material as a coating on an interior surface of the dispensing nozzle 15.

Substantially (or entirely) the whole internal surface of the nozzle assembly 3 may be hydrophilic.

Substantially (or entirely) the whole of the nozzle assembly may be made of a hydrophilic material.

In one embodiment, the hydrophilic internal surface or material may comprise polychlorotrifluoroethylene (PCTFE) or a perfluoroalkoxy alkane (PFA). For example, the dispensing nozzle 15 of the nozzle assembly 3 or the whole nozzle assembly 3 may be formed of PCTFE or PFA. PCTFE may be preferable because it is more hydrophilic than PFA.

The nozzle assembly may be machined from a single block of a hydrophilic material, such a single block of PCTFE or PFA.

A length of the dispensing nozzle 15 is preferably at least 4 times an internal diameter of the dispensing nozzle 15 (a diameter of a flow path through the dispensing nozzle 15), for example 7 times the internal diameter of the dispensing nozzle 15. For example, in one embodiment an internal diameter of the dispensing nozzle 15 may be 6 mm and a length of the dispensing nozzle 15 may be 42.5 mm. With this configuration, the flows from the different bore holes 19 entering the dispensing nozzle 15 have sufficient space to merge to form a well-developed and substantially uniform velocity profile at the end of the dispensing nozzle.

The length of the dispensing nozzle 15 is measured from the outlets of the plurality of bore holes 19 to the tip 16 of the dispensing nozzle 15.

Preferably at least part of the internal surface of the dispensing nozzle 15 has a surface roughness Ra of less than or equal to 0.5 μm, for example less than or equal to 0.4 μm, or less than or equal to 0.3 μm, or less than or equal to 0.2 μm. In one embodiment, the internal surface may have a surface roughness Ra of 0.2 μm. Substantially (or entirely) the whole internal surface of the dispensing nozzle 15 may have such a surface roughness.

Substantially (or entirely) the whole internal surface of the nozzle assembly 3 may have such a surface roughness.

In one embodiment, the bore holes 19 in the static throttle 17 may have a diameter of 1.2 mm. Of course, in other embodiments the diameter of the holes may be different, for example in the range of 0.8 mm to 1.6 mm.

In use of the apparatus of the present invention, a wafer W is positioned on the spin chuck 1 and controller 8 signals motor 7 to rotate the wafer at a selected rpm. Controller 8 next signals control valve 6 to open the supply 5 of process liquid to the dispenser arm 4.

The process liquid flows through the flow path in the dispenser arm 4 and into the nozzle assembly 3 via the inlet portion 13. The process liquid flows through the static throttle 17 via the plurality of bore holes 19 and into the dispensing nozzle 15. The process liquid then flows through the dispensing nozzle 15 to the tip 16 where it is dispensed from the dispensing nozzle 15 onto the surface of the wafer W.

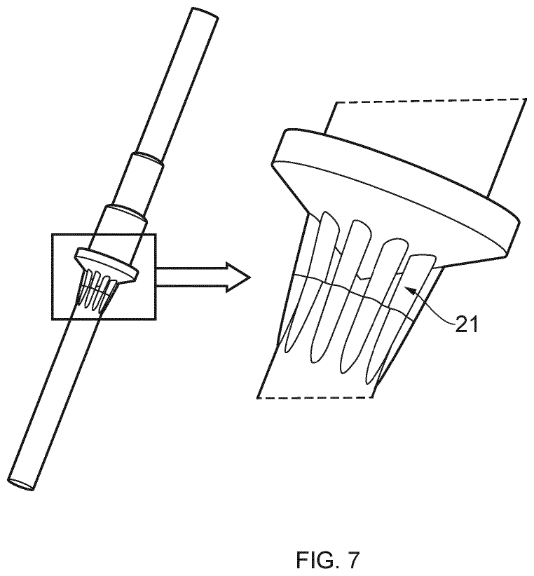

FIG. 7 illustrates a computation fluid flow model of fluid flow through the nozzle assembly illustrated in FIGS. 5 and 6. Individual flow paths 21 through each of the bore holes 9 can be seen in FIG. 7, as can the reduction in width (necking) of the fluid flow path in the nozzle assembly 3 on passing through the static throttle 17.

The results of a computational model of the flow distribution of fluid flow through the nozzle assembly illustrated in FIGS. 5 and 6 have demonstrated that the reduction in flow area through the bore holes 19 in the static throttle 17 causes a reduction in fluid velocity immediately upstream of the static throttle and an increase in fluid velocity through the bore holes 19.

Furthermore, the results of the computational model have demonstrated that the specific length of the dispensing nozzle 15 means that a velocity profile of the fluid flow at the tip 16 of the dispensing nozzle 15 is well-developed and substantially uniform.

At the conclusion of the desired treatment of the wafer W with the process liquid, the controller 8 signals the control valve 6 to close.

The present inventors have found that the specific configuration of the nozzle assembly of the present invention prevents drips from being formed once the supply of process liquid has been stopped, for example when moving the dispense nozzle after carrying out processing of a wafer with the process liquid W. Furthermore, the lack of moving parts in the static throttle 17 prevents or limits the generation or trapping of particles.

Without being bound to any specific theory, it is believed that the use of the static throttle avoids that a static liquid column formed after the supply of the process liquid is stopped is moved. Therefore, it is avoided that a meniscus that is formed at a lower end of the liquid column can be tilted. This in turn avoids that the stopped liquid flows out of the nozzle tip. However, the specific theory by which the specific configuration of the nozzle assembly of the present invention prevents drips from being formed is not an essential part of the present invention.

In an alternative embodiment, the chuck may not be rotated, and may instead merely support the wafer in a stationary position.

The dispensing arm 4 may be movable to controllably position the nozzle assembly 3 over any part of the wafer W, to selectively dispense process liquid onto any part of the wafer W.

1. An apparatus for processing a wafer-shaped article, the apparatus comprising:
a support for supporting the wafer-shaped article; and
a liquid dispenser for dispensing a processing liquid onto a surface of the wafer-shaped article supported by the support;
wherein the liquid dispenser comprises a nozzle assembly, the nozzle assembly comprising:
an inlet portion;
a dispensing nozzle; and
a static throttle between the inlet portion and the dispensing nozzle, the static throttle comprising a plurality of flow passages through which the processing liquid can flow from the inlet portion to the dispensing nozzle.

2. The apparatus according to claim 1, wherein the plurality of flow passages comprise a plurality of bore holes.

3. The apparatus according to claim 1, wherein at least part of an internal surface of the dispensing nozzle is hydrophilic.

4. The apparatus according to claim 1, wherein at least part of an internal surface of the dispensing nozzle comprises a material that has a static water contact angle of less than or equal to 90°, or less than or equal to 80°, or less than or equal to 45°.

5. The apparatus according to claim 1, wherein at least part of an internal surface of the dispensing nozzle comprises PCTFE or PFA.

6. The apparatus according to claim 1, wherein a length of the dispensing nozzle is at least four times an internal diameter of the dispensing nozzle, or at least five times an internal diameter of the dispensing nozzle, or at least six times an internal diameter of the dispensing nozzle, or at least seven times an internal diameter of the dispensing nozzle.

7. The apparatus according to claim 1, wherein an internal diameter of the inlet portion is greater than an internal diameter of the dispensing nozzle.

8. The apparatus according to claim 1, wherein a diameter of the fluid flow through the nozzle assembly is narrowed on passing through the static throttle.

9. The apparatus according to claim 1, wherein for at least some of the plurality of flow passages, an outlet of the flow passage is closer to a central axis of the nozzle assembly than an inlet of the flow passage.

10. The apparatus according to claim 1, wherein the nozzle assembly is machined from a single piece of material.

11. The apparatus according to claim 1, wherein at least part of an internal surface of the dispensing nozzle has a surface roughness Ra of less than or equal to 0.5 μm, or less than or equal to 0.4 μm, or less than or equal to 0.3 μm, or less than or equal to 0.2 μm.

12. The apparatus according to claim 1, wherein the plurality of flow passages each have a diameter d in the range of 0.8 mm≤d≤1.6 mm.

13. The apparatus according to claim 1, further comprising a control valve for turning on and off a supply of processing liquid to the liquid dispenser, the control valve being positioned upstream of the nozzle assembly.

14. A nozzle assembly for use in an apparatus for processing a wafer-shaped article, the nozzle assembly comprising:
an inlet portion;
a dispensing nozzle; and
a static throttle between the inlet portion and the dispensing nozzle, the static throttle comprising a plurality of flow passages through which the processing liquid can flow from the inlet portion to the dispensing nozzle.
